(19) United States
(12) Patent Application Publication
(10) Pub. No.: US 2025/0323330 A1
(43) Pub. Date: Oct. 16, 2025

(54) TESTING DEVICE AND TESTING METHOD FOR THE ENERGY CELL PRODUCTION INDUSTRY, AND METHOD FOR PRODUCING A TESTING DEVICE

(71) Applicant: KÖRBER TECHNOLOGIES GMBH, HAMBURG (DE)

(72) Inventors: Johannes MÜLLER, HAMBURG (DE); Christian Frédéric ADOLFF, HAMBRUG (DE); Thomas ERDMANN, HAMBURG (DE); Norbert HENNIG, GEESTHACHT (DE); Ronald HROCH, TRITTAU (DE); Jannik ROHMANN, FITZEN (DE); Karsten MEINKE, MÖLLN (DE)

(21) Appl. No.: 18/870,555

(22) PCT Filed: Jun. 7, 2023
(86) PCT No.: PCT/EP2023/065107

§ 371 Date: Nov. 29, 2024

(30) Foreign Application Priority Data
Jun. 7, 2022 (DE) 102022205768.6

(51) Int. Cl. H01M 10/42; G01R 31/36

(52) U.S. Cl. CPC H01M 10/4285; G01R 31/3644

(57) ABSTRACT

Disclosed is a testing device for the energy cell production industry, wherein the testing device is designed for testing planar elements that are suitable for forming a cell stack, wherein
the testing device comprises multiple testing units which can be moved relative to a stationary part of the testing device by means of a conveying apparatus, wherein
the testing units each comprise at least two contact surfaces for making electrical and/or signal-transmitting contact with a planar element that is to be tested, wherein
the testing units each comprise a carrier which has electrically insulating properties and by means of which the contact surfaces of the relevant testing unit are supported in a predefined position and orientation with respect to one another, wherein
the carriers of the testing units are fastened to the conveying apparatus.

The present invention relates to a testing device for the energy cell production industry, which is designed for testing planar elements that are suitable for forming a cell stack. Furthermore, the invention relates to a corresponding testing method and to a production method for producing a testing device.

Energy cells or energy storage cells such as battery cells are used for galvanic accumulators, for example in motor vehicles, other land vehicles, ships and airplanes, where a considerable amount of energy must be retrievably stored for long periods of time. For this purpose, such energy cells have a structure consisting of a plurality of planar elements stacked to form a stack, hereinafter referred to as a cell stack. These planar elements are formed by monocells, for example. Monocells are alternating anode sheets and cathode sheets, also known as electrodes, which are separated from each other by separator sheets. A monocell therefore typically has the following layer sequence: separator-electrode (e.g. anode)-separator-electrode (e.g. cathode).

The planar elements are pre-cut in the production process and then placed on top of each other in the predetermined sequence to form the cell stacks and joined together, for example by lamination.

Devices for producing battery cells are known, for example, from WO 2016/041713 A1 and DE 10 2017 216 213 A1.

The planar elements may be damaged during the production process. In the case of planar elements in the form of monocells, for example, the separator may be damaged during production. If a monocell with a damaged separator is used to form the cell stack, this can negatively affect the functionality and service life of the cell stack.

Energy cells can also be fuel cells or solar cells, for example, where planar elements can also be damaged during production.

It is therefore known in principle from the prior art to test planar elements before the stacking process and, if necessary, to eject them from the production process so that only flawless planar elements are used to form a cell stack.

Such test procedures must take into account the production output and conveying speed of current production systems. It is therefore known in principle from the prior art to provide test apparatuses that travel together with the planar elements in the production process and alternately test the planar elements. For this purpose, the test apparatus actively contacts what are known as conductor lugs, which are part of the electrodes of the planar elements. However, the performance of the machine is limited in such test procedures due to the discontinuous movements. Furthermore, the planar elements can be damaged if they contact the conductor lugs.

The object of the present application is to provide an improved testing device for testing planar elements, a corresponding testing method and a production method for a testing device.

The object is achieved by the features of the independent claims. Further preferred embodiments of the invention can be found in the dependent claims, the figures, and the associated description.

According to a first aspect of this application, a testing device for the energy cell production industry is proposed to solve the problem, wherein the testing device is designed for testing planar elements that are suitable for forming a cell stack, wherein the testing device comprises multiple testing units which can be moved relative to a stationary part of the testing device by means of a conveying apparatus, wherein the testing units each comprise at least two contact surfaces for making electrical and/or signal-transmitting contact with a planar element that is to be tested, wherein the testing units each comprise a carrier which has electrically insulating wherein the testing units each comprise a carrier which has electrically insulating properties and by means of which the contact surfaces of the relevant testing unit are supported in a predefined position and orientation with respect to one another, wherein the carriers of the testing units are fastened to the conveying apparatus.

By positioning the contact surfaces using the carrier, they can be easily fastened to the conveying apparatus. Furthermore, the contact surfaces of each testing unit are electrically insulated from each other by the insulating properties of the carrier, with the result that a planar element can be tested without interference from contact with the contact surfaces of a testing unit. For this purpose, the contact surfaces are preferably connected or connectable to a measuring device. Furthermore, the contact surfaces are electrically insulated from the conveying apparatus by the carrier, with the result that, for example, the conveying apparatus can be designed to be electrically conductive. The carrier element can, for example, be formed only in part from an electrically insulating material, for example only on the surface. Preferably, however, the carrier consists entirely of an electrically insulating material such as plastic.

Preferably, the planar elements to be tested are monocells.

Preferably, the number of carriers fastened to the conveying apparatus is a multiple of three or four. In particular, exactly 12 carriers have proven to be advantageous because this number represents an ideal compromise between the parallelization of measurements on one side and a still acceptable number of measuring devices on the other.

Preferably, the conveying apparatus is formed by a rotatably mounted drum, on the radially lateral surface of which the testing units are arranged. This means that the planar elements to be tested can be measured while they are being moved on a circular path; this makes it particularly easy and efficient to carry out a measurement during a conveying movement of the planar elements. In such a case, the testing device can also be called a test drum.

It is further proposed that the testing units each comprise a first and a second contact surface which are designed for making electrical and/or signal-transmitting contact with two electrodes of a planar element when the planar element is in contact with the testing unit, wherein the testing units each comprise a third contact surface for making electrical and/or signal-transmitting contact with a separator of the planar element in contact with the testing unit.

This arrangement of the three contact surfaces of a testing unit on the carrier allows the separators of a monocell to be tested separately from each other in an advantageous manner without having to remove the monocell from the testing unit. The third contact surface therefore serves as a temporary electrode which is associated with the testing device and by means of which an external separator of the planar element can be tested. The disclosure of this application is intended to also explicitly include the proposed testing device together with one planar element or multiple planar elements, for example in the form of monocells, which is or are mounted in the testing units.

Preferably, the contact surfaces are each formed by a metal sheet. In practice, it has proven advantageous to use metal sheets because they can easily be shaped into the desired form and at the same time form a planar and thus gentle support for the conductor lugs. Preferably, the metal sheets are made of materials with very good electrical conductivity, for example copper, gold, silver, nickel, aluminum or steel. It is also conceivable to use refined metal sheets, for example metal sheets with a coating of nickel and/or gold.

Preferably, the contact surfaces are fastened to the carrier by means of an integral bond or form-fitting connection. An adhesive bond, for example, can be considered to be an integral bond. In the case of a form-fitting connection, this can be formed, for example, by a screw connection, it having proven advantageous to screw the corresponding screws to the contact surfaces from the side of the conveying apparatus; this ensures that the planar elements are in contact with the contact surface during the test procedure without any interference from a screw connection. If the conveying apparatus is formed by a rotatably mounted drum, the contact surfaces are correspondingly screwed to the carrier from radially inside.

Preferably, the carrier is formed by a, preferably one-piece, detachable carrier element which is fastened to the conveying apparatus by a fastening means. Preferably, the fastening means is formed by a fastening means that can be detached by means of a tool. Further preferably, the fastening means is formed by countersunk screws, so that the screw head does not protrude from the top of the carrier element to which the contact surfaces are also fastened. A screw connection also offers the advantage that individual testing units can be replaced with little effort if necessary, for example in the event of damage or for maintenance activities. The testing units thus form modules that can be changed as a whole. The contact surfaces can be mounted on the carrier before the carrier is fastened to the conveying apparatus; this reduces the downtime of the testing device during assembly or maintenance work.

The carrier is preferably formed by a dielectric structure; for example, the carrier is formed by a plastic part. For example, the carrier can be a cast part or a 3D-printed part.

If the conveying apparatus is formed by a drum, different geometries can be considered for the carrier: If the drum has a cylindrical lateral surface, then the carrier preferably has on its bottom, which faces the drum, a concave surface with a radius corresponding to the drum. If the lateral surface has a plurality of flat surfaces, then the carrier preferably has a flat surface on its bottom, which faces the drum. Depending on the design of the contact surfaces, the top of the carrier, which faces the contact surfaces, can be flat or convex. In a first embodiment, the surface of the contact surfaces is convexly shaped, so that the contact surface formed by a metal sheet is bent in such a way that it rests flat on the convex top of the carrier. In this way, the side of the contact surface facing the planar element is also concave. In a second embodiment, the metal sheet forming the contact surface is thicker than in the first embodiment. The metal sheet can thus lie flat on the flat top of the carrier. The concave shape of the side of the contact surface that is in contact with the planar element during operation can be produced, for example, by machining.

When, in the context of this application, convex or concave surfaces of the carrier or the contact surface are mentioned, this geometry refers to a corresponding sectional surface of the mounted carriers or contact surfaces, which is orthogonal to an axis of rotation of the drum.

As an alternative to the design of the carrier as a detachable carrier element, the carrier can also be formed by an adhesive layer. The adhesive layer then also has electrically insulating properties. The adhesive electrically insulates the contact surfaces from each other and from the conveying apparatus; furthermore, the adhesive can be used to easily determine the orientation and arrangement of the contact surfaces of a testing unit relative to each other.

It is further proposed that recesses are provided in a top of the carrier and are designed to correspond in shape to the contact surfaces. The recesses allow the contact surfaces to be more reliably oriented.

Preferably, the carrier has multiple air ducts which fluidically connect a bottom of the carrier to a top of the carrier. The air ducts can, for example, be connected to a pipe system of the conveying apparatus and be subjected to a negative pressure by means of said system. Preferably, at least one of the contact surfaces per testing unit has at least one flow-through region which is in operative connection with at least one of the air ducts of the relevant carrier. In this way, the flow-through region of the contact surfaces can also be subjected to a negative pressure so that the planar element to be tested is sucked toward the contact surfaces.

Preferably, the flow cross section of the air duct on the top of the carrier is smaller than the flow cross section of the flow-through region of the contact surface that is in operative connection with said air duct. In this way, the holding force acting on the planar elements due to the negative pressure can be distributed over a larger area, as a result of which the planar element can be contacted gently by the testing unit. The smaller flow cross sections of the air ducts of the carrier element increase the stability of the carrier element and create sufficient space for fastening means, both for fastening the carrier to the conveying apparatus and for fastening the contact surfaces to the carrier.

The planar elements, in particular the conductor lugs, can be held particularly gently by means of negative pressure since there is no need for grippers and/or clamps that can damage the conductor lugs. The flow-through region can be provided on the first, second and/or third contact surface. The flow-through region can be formed, for example, by one or more retaining holes or by the pores of an air-permeable, porous material. Such a porous material can be produced, for example, by producing the carrier in a 3D printing process. This is done, for example, by reducing the material density in the flow-through region. The porosity of the material must be selected in such a way that suction of the planar element is possible.

Alternatively, however, it is also possible for the planar elements to be held against the testing units by mechanical means, for example by belts or rollers.

Preferably, the carrier comprises at least one cable duct in which a cable that is connected electrically and/or for signal transmission to one of the contact surfaces is guided. The cable duct allows for predefined routing and storage of the cable, so that possible interference can be reduced. Preferably, the cable is a coaxial cable with the following structure, from radially inside to radially outside: inner conductor, insulation, outer conductor and protective sheath. The protective sheath preferably does not extend completely to a soldering point through which the inner conductor is connected to the relevant contact surface. By means of a screw which is screwed via its thread to the carrier, the outer conductor, in a portion not covered by the protective sheath, can be pressed against a part of the conveying apparatus that is connected to ground, thus reducing interference. The contact surfaces are preferably connected to the inner conductor of the cables by means of a solder connection. In order to reduce the interference as much as possible, the outer conductor, which serves as shielding, preferably extends to just before the soldering point. Preferably, the length of the part of the cable not sheathed by an outer conductor is less than 1 cm, more preferably less than 0.5 cm, particularly preferably less than 0.1 cm. Each contact surface is preferably connected to a separate cable; preferably, each cable is also routed in its own cable duct of the relevant carrier.

The above-proposed recesses, the air ducts and/or the cable ducts of the carrier can be provided not only in the case of the detachable carrier element, but also when the carrier is formed by an adhesive layer. In such a case, the adhesive can, for example, be poured and/or distributed around negative molds provided for this purpose. Alternatively, however, functional units such as the cables or the contact surfaces can themselves form such a negative mold.

According to a further preferred embodiment, it is proposed that the testing units are each designed to receive and transport a planar element. Preferably, the third contact surface simultaneously forms a transport support for the relevant planar element or at least part of the transport support. This means that the transport support simultaneously performs both the function of transporting a planar element and the function of connecting a separator of the transported planar element electrically or for signal transmission. If, for example, a planar element in the form of a monocell is transported in the testing unit, one of the separators of the planar element to be tested preferably rests on the transport support of the relevant testing unit. The two electrodes of the planar element are then contacted by the first and the second contact surface by means of the aforementioned conductor lugs which protrude beyond the base of the separators.

According to an additional preferred embodiment, a pure transport support can also be provided instead of the third contact surface. In this embodiment, the pure transport support preferably consists of an insulating material, for example to reduce stray capacitances during measurement by means of the first and second contact surface. Preferably, the pure transport support is formed by a surface portion of the carrier provided for this purpose.

In this way, the planar elements positioned in the testing units can be transported by means of the conveying apparatus, it being possible to test the planar elements by means of the contact surfaces during the transportation process. In order to prevent the planar elements from slipping during transport, the design described above can be used, in which the contact surfaces can be subjected to negative pressure.

Preferably, the planar extension of the third contact surface corresponds to the surface of the electrodes of the relevant planar element without their conductor lugs. Preferably, the planar extension of the third contact surface deviates from the planar extension of the electrodes by less than 100%, preferably less than 50%, more preferably less than 25%, in particular less than 10%. In this way, the third contact surface forms, with the nearest electrode of the adjacent planar element, an electrode pair which provides measurement results suitable for quality assessment.

As an alternative to testing units that are simultaneously designed to receive and transport the planar elements, a transport system for transporting planar elements along a conveying path from a receiving point to a delivery point can also be provided, for example, wherein the conveying apparatus is designed to bring one or more of its testing units into contact with a planar element while said element is being transported by the transport system, wherein the contact between the testing unit and the corresponding planar element is maintained along some of the conveying path or the entire conveying path. In this embodiment, the transport system is responsible for conveying the planar elements, while the testing device is responsible for testing the planar elements. The testing device is preferably designed to press the testing units with a predefined force against the planar elements transported by the transport system.

If the transport system is formed by a transport drum on whose lateral surface the planar elements are moved on a circular path, the conveying apparatus is designed to guide the testing units over at least part of a corresponding circular path. This can be implemented, for example, by having the conveying apparatus move the testing units on a crescent-shaped path that corresponds to the geometry of the transport drum.

Preferably, at least one measuring device is provided, wherein at least two of the contact surfaces of each of the testing units can be connected to the at least one measuring device by means of a switching matrix.

If the testing unit comprises at least two contact surfaces, at least one of the two separators of a monocell can be measured.

Preferably, the testing units each comprise at least three contact surfaces, more preferably exactly three contact surfaces.

Preferably, the switching matrix is designed to wire the at least two or three contact surfaces of one of the testing units differently so that measurements can be carried out by means of the at least one measuring device in a predetermined electrical circuit or in different electrical circuits.

The switching matrix in the context of this application preferably comprises at least one input channel and at least one output channel, preferably multiple output channels, the input channel(s) being advantageously connected or able to be connected to the output channel(s) in a predefined configuration.

By connecting the at least two contact surfaces of the testing units to the output channels of the switching matrix, these channels can be connected to the at least one measuring device which is connected to the at least one input channel. In principle, it is also possible to connect the at least one measuring device to the switching matrix via two or more input channels.

Preferably, all contact surfaces of the testing units are connected to the switching matrix on the output channel side. Also preferably, all measuring devices are also connected to the switching matrix on the input channel side.

It goes without saying that the switching matrix can in principle comprise other input channels and/or other output channels that are not connected to the at least one measuring device or the contact surfaces. For example, additional input channels can be provided via which a voltage source is connected to the switching matrix.

At least two of the at least three contact surfaces of a testing unit can preferably be connected to the measuring device at the same time. For example, conclusions can be drawn about the system status of the corresponding planar element on the basis of the measurement of an impedance, an ohmic resistance or the electrical capacitance between two of the at least three contact surfaces. The ohmic resistance can be measured with direct current or as the reciprocal value of the real part of the complex admittance with an alternating voltage, for example at a frequency of 1 kHz, 10 KHz or 1000 kHz. The capacitance can also be measured with alternating voltage. For example, a breakdown measurement can be used to detect foreign bodies whose diameter or extent is less than the layer thickness of the separator. If, for example, the planar element to be tested is formed by a monocell as described at the outset, the electrical resistance between two electrodes can be reduced if the separator arranged between these electrodes is damaged.

The at least three, preferably exactly three, contact surfaces per testing unit mean that what is known as a 3-port measurement of the planar element arranged on the testing unit can be carried out. This has the advantage that the two separators of a monocell can be tested separately and/or together. Thus, not only the separator of the planar element arranged between the first and second electrode can be tested, but also the external separator, which is only contacted by an electrode of a neighboring planar element when the cell stack is formed. The corresponding measurements can be carried out by intelligently connecting the contact surfaces to the at least one measuring device.

According to a preferred embodiment, multiple measuring devices are provided, wherein the switching matrix is designed to connect, electrically and/or for signal transmission, one or more of the contact surfaces of each of the testing units to different measuring devices. The planar elements can thus be connected to different measuring devices without being removed from the relevant testing unit, which allows different parameters to be measured in a way that is particularly gentle on the product. It is also possible, for example, for planar elements in contact with or mounted on different testing units to be tested in parallel.

Preferably, the switching matrix is designed to connect the first and the second contact surface to the same measuring device at the same time, to connect the first and the third contact surface to the same measuring device at the same time, and/or to connect the second and the third contact surface to the same measuring device at the same time. If, for example, a planar element in the form of a monocell is in contact with a testing unit for the purpose of testing, then, for example, the three contact surfaces of a testing unit contact the inserted planar element as follows:

A first separator of the planar element rests on the third contact surface; the conductor lug of a first electrode adjacent to the first separator, for example in the form of an anode, is in contact with the first contact surface; the conductor lug of a second electrode, separated from the first electrode by a second separator, for example in the form of a cathode, is in contact with the second contact surface.

If the first and second contact surface are connected to the at least one measuring device at the same time, then the second separator arranged therebetween can be tested.

If the first and the third contact surface are connected to the least one measuring device at the same time, then the first separator, which is arranged on the outside of the planar element, can be tested.

If the second and third contact surface are connected to a measuring device at the same time, then the first and second separator can be tested at the same time. Depending on the switching configuration, the first and second separator are then arranged in a series or parallel connection between the second and third contact surface.

These switching configurations, which can be adjusted by means of the switching matrix, allow comprehensive testing of the planar elements to be tested.

Preferably, the switching matrix is designed to wire the three contact surfaces of each of the testing units differently so that measurements can be carried out in different electrical circuits by means of the at least one measuring device. Depending on whether, for example, the first or the second separator or both separators of a monocell are to be tested, the switching configuration can be different. In this way, a large number of measurements can be carried out on the planar element while it is in contact with the testing unit. By avoiding having to transfer the planar element to be tested to an additional testing device, the planar element can be measured in a way that is particularly gentle on the product. In particular, the extremely sensitive conductor lugs of the electrodes, which were already mentioned at the outset, do not have to be contacted multiple times. For example, two or more contact surfaces of a testing unit can also be short-circuited together.

Preferably, the switching matrix is designed to connect one or more of the contact surfaces of each of the testing units to a voltage source and/or to ground. These types of connections can allow for additional switching configurations, so that the measurement options can be expanded.

Preferably, the switching matrix comprises a plurality of relays for connecting the contact surfaces to each other and/or one or more of the contact surfaces to one or more measuring devices. The relays can be controlled or regulated by means of a control unit, for example. Due to the large number of switching combinations, it has proven to be advantageous to operate the switching matrix with relays. The switching matrix and therefore also the relays can, for example, be based on the position of the conveying apparatus relative to the stationary part of the testing device. Of course, other input parameters can be used alternatively or additionally to control or regulate the switching matrix or the relays. The relays are also preferably used to connect one or more contact surfaces to ground and/or to connect them to a voltage source. The main advantage of the relays is passive, galvanically isolated switching and the minimally invasive behavior with regard to changes in the measuring distance. Furthermore, relays are able to conduct direct current and alternating current; switching transistors are only able to do this to a limited extent. Furthermore, switching transistors have a considerable influence on the measuring path.

Preferably, the switching matrix is part of the conveying apparatus. In this way, the connection to the conveying apparatus can be carried out efficiently.

Furthermore, it is advantageous if the at least one measuring device is designed to measure an electrical capacitance and/or the ohmic resistance, more generally the real part and/or the imaginary part of the electrical impedance, and/or to carry out a breakdown measurement. By testing the planar elements by measuring the ohmic resistance and/or the electrical capacitance, reliable conclusions can be drawn about the system status of the planar elements to be tested.

Preferably, the at least one measuring device is a component of the stationary part of the testing device. Accordingly, the at least one measuring device does not have to be moved with the conveying apparatus. This is particularly advantageous if the testing device comprises a plurality of measuring devices. Furthermore, the measuring devices can also be advantageously connected to the contact surfaces of different testing units so that a smaller number of measuring devices is required. In principle, however, it is also possible to integrate one or more of the measuring devices into the conveying apparatus.

According to an additional preferred embodiment, it is proposed that the electrical and/or signal connection of the conveying apparatus to the stationary part is made by means of a sliding contact apparatus. A sliding contact apparatus has proven to be advantageous for connecting the moving, for example rotating, conveying apparatus to the stationary part of the testing device electrically and/or by signal.

According to a second aspect of this application, a production method for producing a testing device is proposed to solve the problem, wherein in a method step a), oversized metal sheets are provided to form the contact surfaces; in a method step b), the metal sheets are fastened to the conveying apparatus by means of the carrier; and in a method step c), the metal sheets fastened to the conveying apparatus by means of the carrier are machined by a cutting tool. By means of the proposed method, in particular the surface of the contact surfaces can be machined in such a way that they have a predefined surface geometry. For example, a metal sheet can be divided into sections by means of machining to form separate contact surfaces of a testing unit. Alternatively or additionally, the flow-through regions, which can be subjected to negative pressure during operation, can also be formed by machining, for example by drillings.

According to a third aspect of this application, the object is achieved by a method for testing planar elements that are provided to form a cell stack for the energy cell production industry. In said method, the planar elements are tested using a testing device as described above, wherein the planar elements to be tested are each in contact with the contact surfaces of one of the testing units.

Preferably, the planar elements are tested during transportation of the planar elements, i.e., while the conveying apparatus is moving relative to the stationary part of the testing device.

More preferably, the detection of a damaged or poor-quality planar element leads to it being ejected from the production process. This can be done, for example, by the testing device itself, or alternatively by a separate apparatus, for example in the form of an ejection drum.

Alternatively or additionally, however, it is also possible for the testing device to record the quality parameters of the planar elements for later use, without necessarily ejecting them from the process. In this way, for example, the stack of formed cells can be classified into different quality classes.

With regard to the technical effects and advantages associated with the proposed method, reference is made to the previous explanations in connection with the testing device.

The invention is explained below using preferred embodiments with reference to the accompanying drawings, in which:

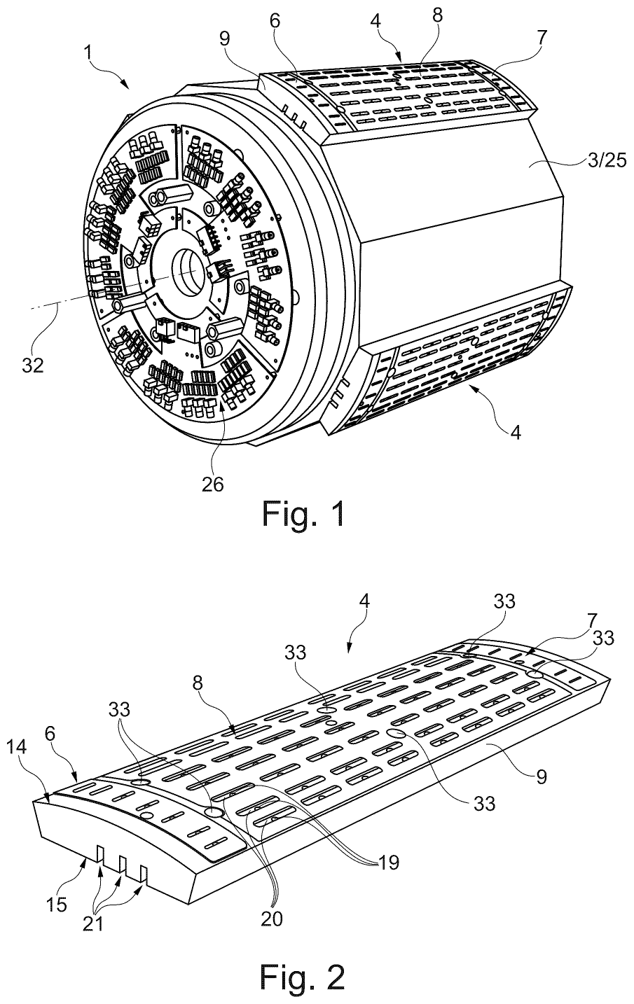

FIG. 1 shows a testing device having a conveying apparatus in the form of a drum without its stationary part;

FIG. 2 shows a carrier having three contact surfaces;

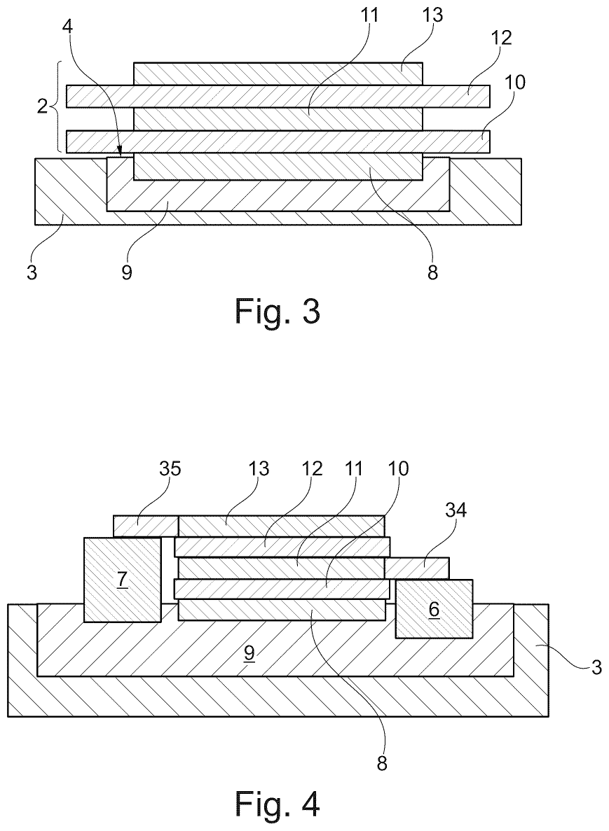

FIG. 3 shows a testing unit having a planar element arranged thereon in a first cross section orthogonal to an axis of rotation of the drum;

FIG. 4 shows a testing unit having a planar element arranged thereon in a first cross section parallel to an axis of rotation of the drum;

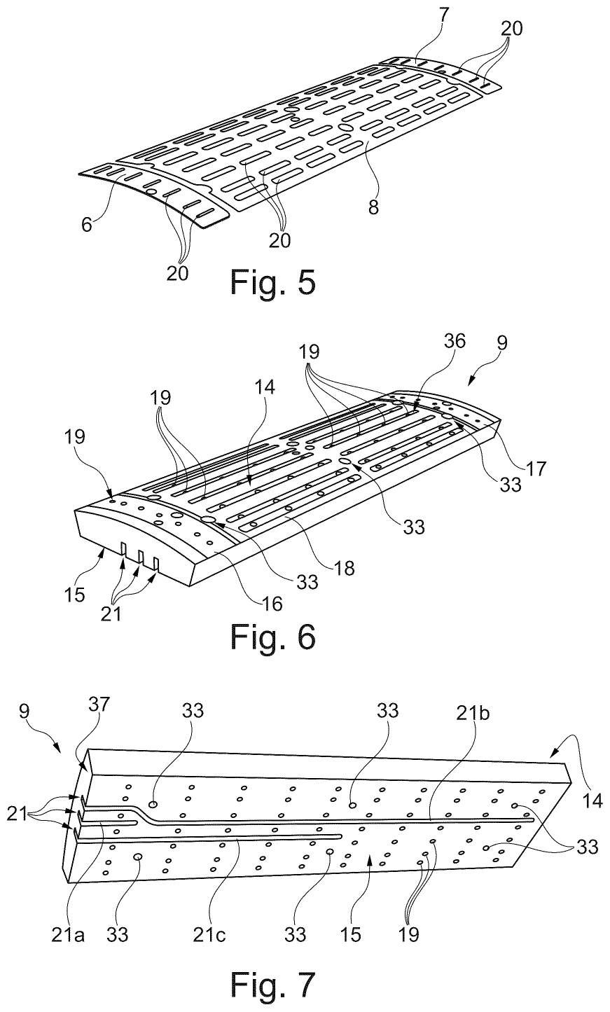

FIG. 5 shows three contact surfaces in a perspective view;

FIG. 6 shows a carrier in a perspective view looking at its top;

FIG. 7 shows a carrier in a perspective view looking at its bottom;

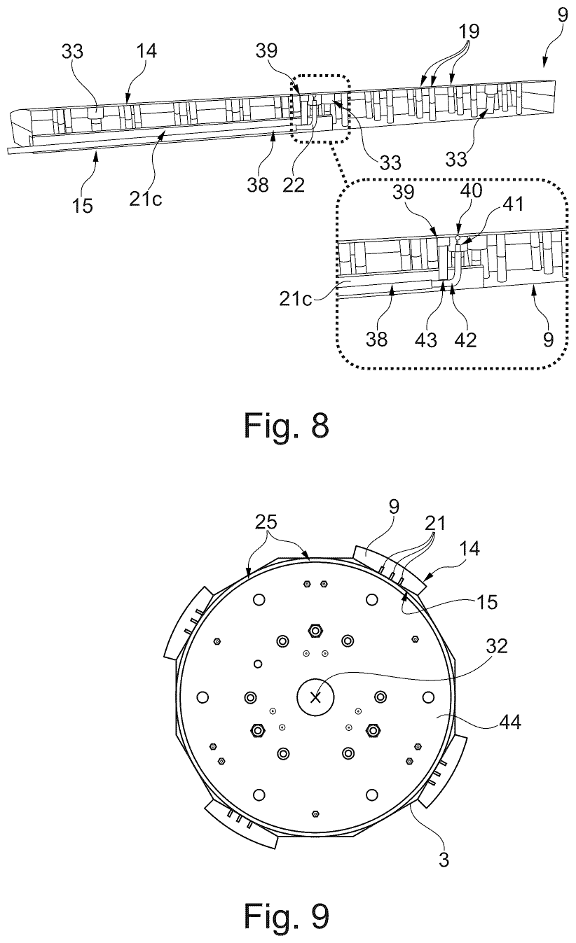

FIG. 8 shows a sectional view of a carrier having a cable laid therein;

FIG. 9 shows a view of the end face of the conveying apparatus together with a cover;

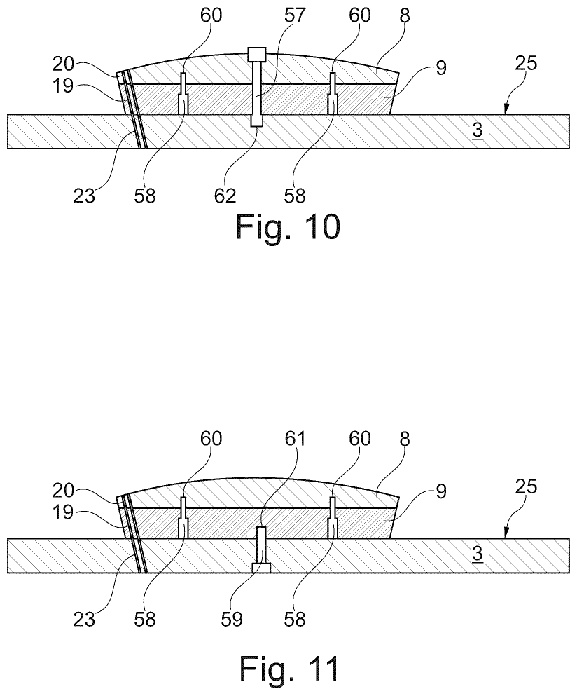

FIG. 10 shows a first embodiment of a testing unit having a carrier that can be detachably fastened to the conveying apparatus;

FIG. 11 shows a second embodiment of a testing unit having a carrier that can be detachably fastened to the conveying apparatus;

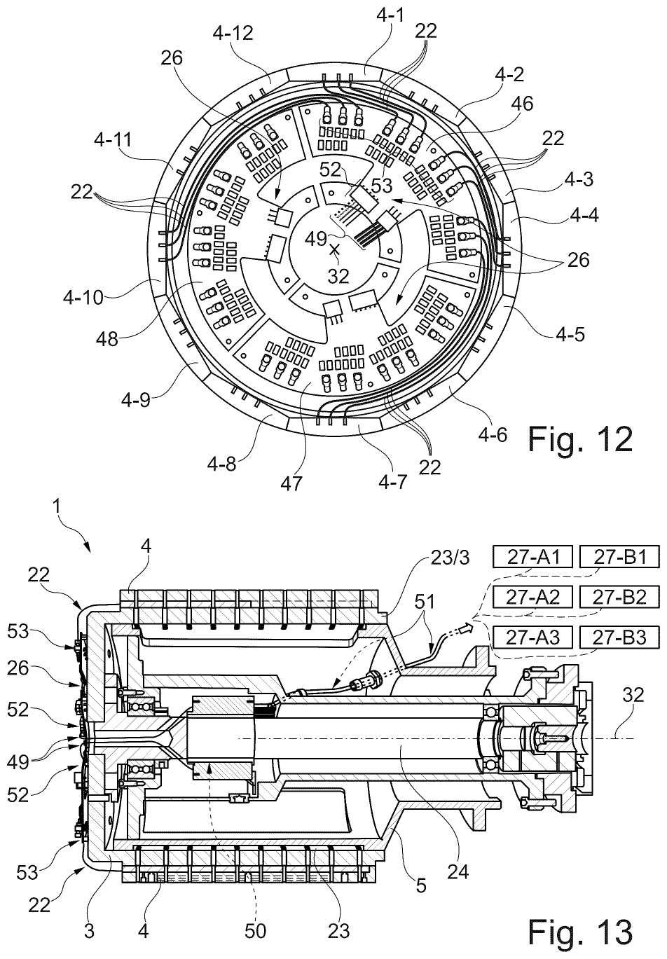

FIG. 12 shows a view of the end face of the conveying apparatus without a cover;

FIG. 13 shows a sectional view of the testing device with a first variant of the wiring;

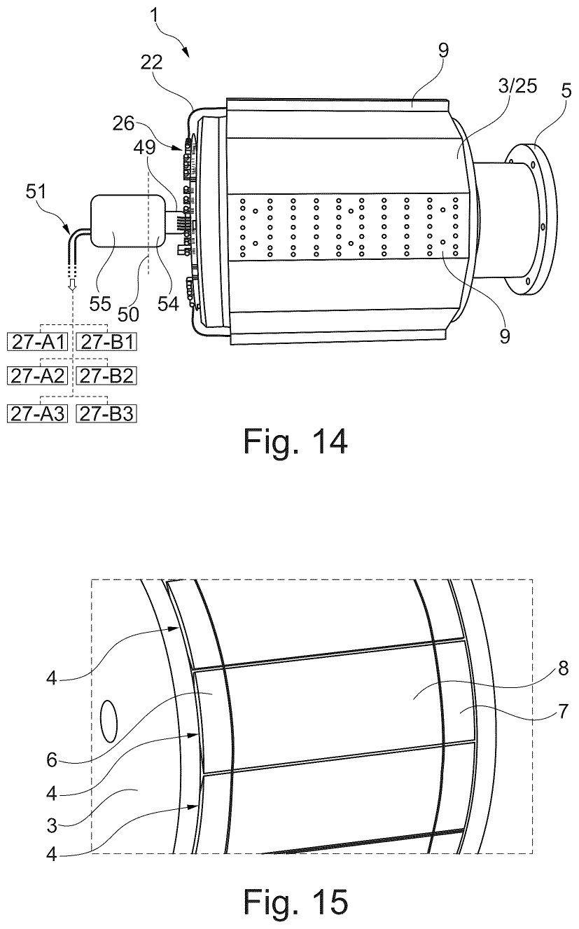

FIG. 14 shows a perspective view of the testing device with a second variant of the wiring;

FIG. 15 shows a perspective view of a conveying apparatus having adhesively bonded contact surfaces;

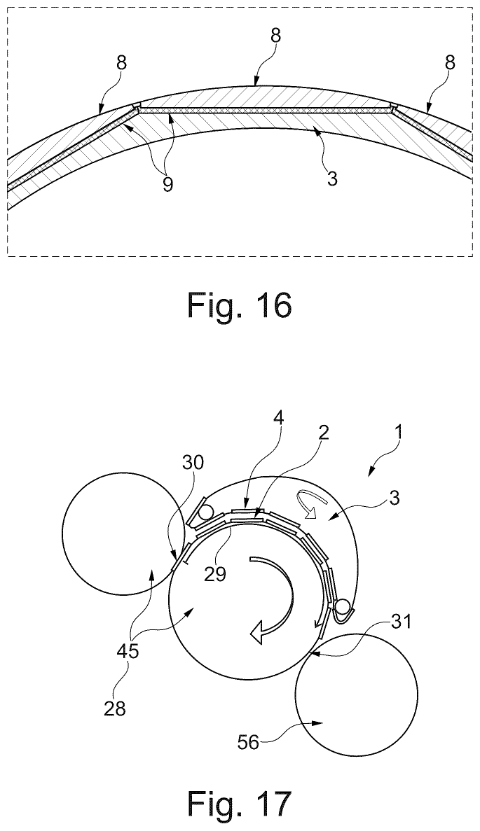

FIG. 16 shows a sectional view of a conveying apparatus having adhesively bonded contact surfaces; and

FIG. 17 shows another embodiment of the testing device.

FIG. 1 shows a testing device 1 without its stationary part 5, which is shown in FIG. 13, however. The testing device 1 comprises a conveying apparatus 3 which is formed by a drum mounted so as to be rotatable about an axis of rotation 32. Twelve flat surfaces are provided on a lateral surface 25 of the conveying apparatus 3, with a carrier 9 being fastened to only every third of these flat surfaces; one of the carriers 9 cannot be seen in the perspective shown. The fact that not every flat surface is occupied by a carrier 9 serves to improve the illustration; in principle, a carrier 9 is fastened to all twelve flat surfaces of the conveying apparatus 3. In principle, the conveying apparatus can have any number of receiving surfaces for the carriers, although, for the purpose of parallelization, which is explained in more detail below, a number that is divisible by three or four is particularly suitable. Furthermore, it can be seen that a first and a second contact surface 6 and 7 as well as a third contact surface 8, which is located therebetween, are provided on each of the carriers 9. Each carrier 9 and the contact surfaces 6, 7 and 8 arranged thereon form a modular unit in the form of a testing unit 4, which is explained below with reference to FIG. 2. Furthermore, it can be seen that a switching matrix 26 is provided at an end face of the conveying apparatus 3 and serves to connect the contact surfaces 6, 7 and 8 to measuring devices 27 (see FIG. 13).

FIG. 2 shows the modular unit consisting of a carrier 9 and the contact surfaces 6, 7 and 8 disposed thereon. In this exemplary embodiment, the contact surfaces 6, 7, 8 are adhesively bonded to the carrier 9 so that they are positioned in a predefined orientation and arrangement relative to one another by the carrier 9. Furthermore, through-openings 33 are provided, via which the carrier 9 can be fastened to the flat surfaces of the conveying apparatus 3 by means of countersunk screws (not shown). It can also be seen that a bottom 15 of the carrier 9 has a flat face, so that it lies flat against the likewise flat face of the lateral surface 25 of the conveying apparatus 3 (cf. FIG. 1).

A top 14 of the carrier 9 has a convex curvature, against which the contact surfaces 6, 7 and 8 also lie flat. The contact surfaces 6, 7 and 8 formed from metal sheets can be adapted to the convex geometry of the carrier 9 and adhesively bonded thereto without great effort.

In this exemplary embodiment, the carrier 9 consists of an electrically non-conductive plastic. Alternatively, however, the carrier 9 can also be made of other non-conductive materials. The contact surfaces 6, 7, 8 are thus mounted so as to be electrically insulated with respect to one another and with respect to the conveying apparatus 3.

Furthermore, air ducts 19 can be seen, which interact with a flow-through region 20 of the contact surfaces. The reference signs of the air ducts 19 are provided in FIG. 3 only as an example on the third contact surface 8; the first and second contact surface 6 and 7 also have a flow-through region 20 which is in operative connection with an air duct 19. In this way, the flow-through regions 20 of the contact surfaces 6, 7 and 8 can be subjected to a negative pressure so that a planar element 2 to be tested (cf. FIGS. 3 and 4) is sucked onto the contact surfaces 6, 7 and 8.

FIG. 3 is a schematic sectional view of a planar element 2 arranged on the testing unit 4, the section being in a plane orthogonal to the axis of rotation 32 (cf. FIG. 1) of the conveying apparatus 3.

The planar element 2 shown in FIGS. 3 and 4 has the following layer structure from bottom to top: first separator 10—first electrode 11—second separator 12—second electrode 13. In this exemplary embodiment, the first electrode 11 is formed by an anode and the second electrode 13 by a cathode. In principle, however, the first electrode 11 can also be formed by a cathode and the second electrode 13 by an anode.

The sectional view in FIG. 3 shows the testing units 4 from FIG. 1. In the sectional view shown in FIG. 3, it can be seen that the third contact surface 8 is supported by the carrier 9. Since the carrier 9 is made of an electrically non-conductive material, the third contact surface 8 is mounted so as to be electrically insulated with respect to the conveying apparatus 3. The first separator 10 of the planar element 2 is in contact with the third contact surface 8, which simultaneously forms a suitable transport support for the planar element 2. It can also be seen that the flat extension of the third contact surface 8 coincides substantially with the base surface of the first and second electrode 11 and 13 without taking into account the conductor lugs 34 and 35 (not shown here) (cf. FIG. 4). In this way, the third contact surface 8 together with the first electrode 11, which is located above the first separator 10, can form an electrode pair that is suitable for testing the first separator 10, which is located therebetween. The first electrode 11 is then contacted by placing its conductor lug 34 on the first contact surface 6.

FIG. 3 also shows that the first electrode 11 is followed by the second separator 12 and the second electrode 13. The first electrode 11 and the second electrode 13 therefore form an electrode pair that is suitable for testing the second separator 12, which is located therebetween.

FIG. 4 is an additional sectional view of the planar element 2 arranged on the testing unit 4, the section extending in a plane parallel to the axis of rotation 32 (cf. FIG. 1) of the conveying apparatus 3. In this view, it can be seen that the first electrode 11 uses its conductor lug 34 to contact the first contact surface 6. It can also be seen that the second electrode 13 uses its conductor lug 35 to contact the second contact surface 7. In order to prevent the conductor lugs 34, 35 from snapping off, the contact surfaces 6, 7 have a correspondingly adapted height in the radial direction; the height of the first contact surface 6 in the radial direction is therefore less than the height of the second contact surface 7.

FIG. 5 shows the contact surfaces 6, 7, 8 without the carrier 9. It can be seen that these surfaces are formed by metal sheets, for example made of copper, gold, silver, nickel, aluminum, or steel; furthermore, metal sheets with a coating of nickel and/or gold are also conceivable.

FIG. 6 shows the carrier 9 without the contact surfaces 6, 7 and 8 applied thereto. At the points where the contact surfaces 6, 7 and 8 of FIG. 5 are located, recesses 16, 17 and 18 which correspond to the planar extension of the contact surfaces 6, 7 and 8 are provided in the top 14 of the carrier 9. The recess 16 serves to position and orient the first contact surface 6; the recess 17 serves to position and orient the second contact surface 7; the recess 18 serves to position and orient the third contact surface 8. The carrier 9 shown in FIG. 6 is formed from a one-piece plastic part; such a plastic carrier can be, for example, a cast part or a 3D-printed part. Furthermore, it can be seen in FIG. 6 that four of the air ducts 19 which are in operative connection with the third contact surface 8 meet the top 14 at the groove base of a groove 36. In this way, four of the air ducts 19 can be fluidically connected to one another before they pass into the flow-through regions 20 of the third contact surface 8 (cf. FIG. 5).

FIG. 7 shows the bottom 14 of the carrier 9, along which the cable ducts 21 extend. A first cable duct 21a is designed to guide a cable 22 (cf. FIGS. 12 and 13) from an end face 37 of the carrier 9 to the first contact surface 6, correspondingly a second cable duct 21b to the second contact surface 7 and a third cable duct 21c to the third contact surface 8 (cf. FIG. 2). The cable ducts 21a, 21b and 21c are open on the bottom 15 and are closed by the attachment of the carrier 9 to the conveying apparatus 3 via the lateral surface 25 of the conveying apparatus 3 (cf. FIG. 1). Furthermore, it can be seen that the air ducts 19 meet the flat bottom 15 of the carrier 9. These ducts can be subjected to negative pressure via the pipe system 23 provided for this purpose (see FIG. 13) of the conveying apparatus 3.

FIG. 8 shows a schematic cross section through the carrier 9 in a plane parallel to the axis of rotation 32 of the conveying apparatus 3; cf. FIG. 1. This view shows the cable 22 which is laid in the cable duct 21c and is connected to the third contact surface 8. The cable 22 is in the form of a coaxial cable: An inner conductor 40 extends radially inside and is soldered to the third contact surface 8. This is followed by an outer conductor 42 which serves for shielding and is separated from the inner conductor 40 by insulation 41. This is followed radially on the outside by a protective sheath 38. The cable 22 extends parallel to the axis of rotation 32 (cf. FIG. 1) in the duct 21c until it meets the soldering point at a right angle, i.e., in the radial direction with respect to the axis of rotation 32. The protective sheath 38 extends as far as shortly before the right-angled change in direction, so that the outer conductor 42 is exposed in a portion of the cable 22. By means of an end face 43 of a ground contact screw 39, which is screwed by means of its thread into the carrier 9, the outer conductor 42 is pressed against the electrically conductive conveying apparatus 3 in order to establish a defined ground contact. In the same way, the cables 22 leading to the first and second contact surface 6 and 7 are laid in the carrier 9.

FIG. 9 shows a front view of the conveying apparatus 3 with carriers 9 mounted thereon. As in FIG. 1, only every third carrier 9 is mounted on the conveying apparatus 3. It can additionally be seen that the cable ducts 21 are also closed on the bottom 15 of the carrier 9 due to the mounting of the carrier 9 on the conveying apparatus 3. Furthermore, a cover 44 is provided, by means of which the switching matrix 26 (see FIG. 12) is covered at the end face.

FIGS. 10 and 11 show two alternatives to the adhesive bonding (shown in FIG. 2) of the contact surfaces 6, 7, and 8 to the carrier 9. In the embodiments of FIGS. 10 and 11, the contact surfaces 6, 7 and 8 can be individually fastened to the carrier 9 by means of detachable screw connections. This principle is explained below in FIGS. 10 and 11 on the basis of the third contact surface 8; however, the first and second contact surface 6 and 7 can be fastened to the carrier 9 in an analogous manner.

FIGS. 10 and 11 show a flat portion of the lateral surface 25 of the conveying apparatus 3 designed as a drum, as already shown in FIG. 1. The contact surface 8 can be screwed to the carrier 9 by means of a screw (not shown) which is screwed in from the radial inside. For this purpose blind hole bores 58 are provided, which completely penetrate the carrier 9 and the blind hole of which is located in the third contact surface 8. An internal thread 60, into which the screw (not shown) engages, is provided in the third contact surface 8. The blind hole 58 bore has a corresponding countersink diameter in the carrier, so that the screw head of the countersunk screw (not shown) is completely countersunk in the carrier 9 when screwed in. By screwing from the radial inside, the top of the contact surface 8 is not affected. The contact surface 8 is screwed to the carrier 9 before the carrier 9 is mounted on the conveying apparatus 3.

In the embodiment according to FIG. 10, the carrier 9 is fastened to the conveying apparatus 3 by means of a blind hole bore 57 which completely penetrates both the contact surface 8 and the carrier 9. The blind hole base and an internal thread 62 are provided in the conveying apparatus 3. Furthermore, the blind hole bore 57 has a countersink diameter so that in the mounted state a screw (not shown) does not protrude from the third contact surface 8, which could result in damage to the planar element 2 mounted thereon.

In the embodiment according to FIG. 11, the unit comprising contact surfaces 6, 7 and 8 (in this plane only the contact surface 8 is visible) is fastened to the conveying apparatus 3 from the radial inside by means of a screw connection. A corresponding blind hole bore 59 completely penetrates the conveying apparatus 3, while a blind hole and an internal thread 61 are provided in the carrier 9. An appropriate countersink diameter is provided so that a screw head of a screw (not shown) does not protrude from the bore.

The bores described here do not necessarily have to be produced by machining.

FIG. 12 shows the electrical and signal-transmission connection of the contact surfaces 6, 7 and 8 of the testing units 4 to the switching matrix 26, which in turn is connected electrically and for signal transmission to measuring devices 27 (cf. FIG. 13). The switching matrix 26 comprises a plurality of relays which are designed to connect the cables 22 to the cables of an input channel cable set 49. In principle, it is possible to connect a planar element 2 resting on a specific testing unit 4 (cf. FIGS. 3 and 4) to any measuring device 27 (cf. FIG. 13) by means of a switching matrix 26. In practice, however, it has proven useful to connect the testing units 4 in parallel with measuring devices 27. This means that a plurality of measuring devices 27 are provided, with each testing unit 4 always being assigned the same measuring devices 27.

By using parallelization, the time available for testing the planar element 2 can be extended. In the embodiment according to FIG. 12, exactly 12 testing units 4 are provided on the conveying apparatus 3.

If no parallelization were provided at all, the planar element 2 located in a testing unit 4 could be tested only over an angular portion of 360°/12=30°; this provides only a correspondingly short period of time.

In the case of parallelization with a factor of 2, the testing units 4 would be alternately assigned to a first set of measuring devices 27-A1 and 27-B1 and the second half of the testing units would be assigned to a second set of measuring devices 27-A2 and 27-B2. The measuring devices with the identification letter “A”—in this case the measuring devices 27-A1 and 27-A2—are designed to measure a capacitance. The measuring devices with the identification letter “B”—here 27-B1 and 27-B2—are designed to measure an ohmic resistance and to carry out a breakdown measurement. In the case of parallelization with a factor of 2, the planar element 2 located in a testing unit 4 can be tested over an angular portion of (360°/12)*2=60°; this provides twice the period of time available in comparison with the previously described case, assuming an identical rotation speed of the conveying apparatus 3.

Parallelization with a factor of 3 will now be described in detail with reference to FIGS. 12 and 13.

First, it can be seen in FIG. 13 that, according to parallelization with a factor of 3, the switching matrix 26 is divided into three electronic units 46, 47 and 48. By means of the cables 22, the contact surfaces 6, 7 and 8 of the testing units 4-1, 4-4, 4-7 and 4-10 are connected to the first electronic unit 46, via which a connection to the measuring devices 27-A1 and 27-B1 is possible. For example, any two of the three contact surfaces 6, 7, 8 of a testing unit 4 can be connected in pairs to a measuring device 27 so that the two separators 10 and 12 of the corresponding planar element 2 (cf. FIGS. 3 and 4) can be tested.

Not shown in FIG. 12 is the wiring of the contact surfaces 6, 7 and 8 of the testing units 4-2, 4-5, 4-8 and 4-11 with the second electronic unit 47, via which a connection to the measuring devices 27-A2 and 27-B2 is made (cf. also FIG. 13).

Likewise not shown in FIG. 3 is the wiring of the contact surfaces 6, 7 and 8 of the testing units 4-3, 4-6, 4-9 and 4-12 with the third electronic unit 48, via which a connection to the measuring devices 27-A3 and 27-B3 is made (cf. also FIG. 13).

For parallelization with a factor of 3, a total of six measuring devices 27-A1 to 27-B3 are required, because different measuring device types (identification letters “A” and “B”) are required for measuring the capacitance and for measuring the resistance and breakdown. Such parallelization makes it possible to test the planar element 2 located in each testing unit 4 over an angular portion of (360°/12)*3=90°. In practice, parallelization with a factor of 3 has proven to be advantageous because it offers an ideal compromise between a still acceptable number of relatively expensive measuring devices 27-A1 to 27-B3 on one side and a sufficiently large measuring portion of 90° and the measuring duration thus available on the other side.

Of course, parallelization by a factor of 4 or 6 is also possible in a corresponding manner. Due to the divisibility of the number 12 by the values 2, 3, 4 and 6, there are essentially four possibilities for parallelization.

In principle, regardless of the parallelization factor, it is of course possible to add one or more additional measuring device types in order to carry out corresponding measurements.

The three electronic units 46, 47, 48 of the switching matrix 26 are mounted on the end face of the conveying apparatus 3 designed as a drum. In this way, the switching matrix 26 is arranged relatively close to the testing units 4, which allows better quality measurement results to be achieved. Furthermore, the switching matrix 26 is easy to mount.

In the exemplary embodiment according to FIG. 12, the 12*3=36 cables 22 are connected to the output channels 53 of the switching matrix 26 which are provided radially on the outside with respect to the axis of rotation 32. The connection to the measuring devices 27-A1 to 27-B3 can then be established via radially inner input channels 52. The input channels 52 and the output channels 53 are connected to each other by means of communication lines and can be wired in the desired manner by means of relays. The input and output channels 52 and 53 each comprise a coaxial connector for connecting corresponding coaxial cables, for example SMA screw connectors.

Of course, the switching matrix 26 can in principle be connected to further lines. For example, it can be connected to a line that serves for grounding or for switching individual or multiple contact surfaces 6, 7 and/or 8 to ground or to a control line for controlling the switching matrix 26.

FIG. 13 shows a sectional view of the testing device 1, from which the electrical and/or signal-transmission connection of the contact surfaces 6, 7 and 8 of the testing units 4 to the measuring devices 27 can be seen. The cables 22 extending from the testing units 4 are connected to the output channels 53 of the switching matrix 26 which is connected to the conveying apparatus 3 for conjoint rotation. Proceeding from the input channels 52 of the switching matrix 26, an input cable set 49 extends into the interior of the conveying apparatus 3 designed as a drum as far as a sliding contact apparatus 50, which is formed by a slip ring. The sliding contact apparatus 50 is located, for example, on a rotating hollow shaft 24 inside the drum. In an alternative embodiment, the sliding contact ring can also be mounted outside the shaft 24, for example on the side of a cover, for example in the region of the stator 55 in FIG. 14. In the region of the input channels 52, the input cable set 49 is guided through the hollow shaft 24 and connected via the sliding contact apparatus 50 in the form of a slip ring to a measuring cable set 51 associated with the stationary part 5 of the testing device. The measuring cable set 51 is then connected to the measuring devices 27-A1 to 27-B3, which are components of the stationary part 5 of the testing device 1.

The input cable set 49 and the measuring cable set 51 comprise—in addition to signal cables that can be directly connected to the cables 22—data and power supply cables that are also connected to the switching matrix 26.

The testing device 1 therefore comprises three cable sets: A first cable set comprises the cables 22 which connect the contact surfaces 6, 7 and 8 of the testing apparatuses 4 to the output channels 53 of the switching matrix 26. An input cable set 49, which is associated with the rotatable conveying apparatus 3, connects the input channels 52 of the switching matrix 26 to the sliding contact apparatus 50. The measuring cable set 51, which is associated with the stationary part 5 of the testing unit 4, connects the sliding contact apparatus 50 to the measuring devices 27 or to other apparatuses, such as a control unit or a voltage source.

Furthermore, FIG. 13 shows the pipe system 23 of the conveying apparatus 3, via which the testing units 4 can also be subjected to negative pressure. It is self-evident that the pipe system 23 is designed to apply negative pressure to only some of the testing apparatuses 4 depending on the angle of rotation of the conveying apparatus 3 relative to the stationary part 5, such that the planar elements 2 are sucked onto the contact surfaces 6, 7 and 8 of the testing apparatuses 4 only in a particular portion (cf. also FIGS. 3 and 4).

FIG. 14 shows an alternative embodiment for wiring compared to the embodiment shown in FIG. 13. The testing device 1 of FIG. 14 is otherwise identical to the testing device 1 according to FIG. 13, however. In the embodiment according to FIG. 14, the input cable set 49 is not guided into the interior of the conveying apparatus 3 designed as a drum, but is connected to a rotor 54 which is arranged in the center of an annular circuit board of a switching matrix 26. By means of a sliding contact apparatus 50, the connection is made to a stator 55, from which a measuring cable set 51 is connected to the measuring devices 27-A1 to 27-B3. In this embodiment, the sliding contact apparatus 50 and the measuring devices 27-A1 to 27-B3 are arranged in front of the end face of the conveying apparatus 3.

FIG. 15 shows an embodiment of the testing device 1 in which the carrier 9 is not formed by a detachable carrier element, but by an adhesive layer. Here too, three contact surfaces 6, 7 and 8 are provided per testing unit 4.

FIG. 16 shows the embodiment from FIG. 15 in a sectional view, with the section here also extending orthogonal to an axis of rotation. The third contact surfaces 8 visible in this illustration are each held on the conveying apparatus 3 by a carrier 9 in the form of an adhesive. Since the adhesive has electrically insulating properties, in this embodiment too the contact surfaces 6, 7 and 8 are electrically insulated from the conveying apparatus 3 and from each other.

This embodiment allows subsequent machining of the contact surfaces 6, 7 and 8, so that the contact surfaces 6, 7 and 8 have an ideal curvature, forming portions of an imaginary cylindrical surface. In this embodiment, the contact surfaces 6, 7 and 8 shown in FIG. 15 are provided in a method step a) in the form of oversized metal sheets. Subsequently, in a method step b), the metal sheets are fastened to the conveying apparatus 3 by means of the carrier 9 made of adhesive. In this case the adhesive can be applied separately for each testing unit 4 or for each contact surface 6, 7 and 8; alternatively, however, the adhesive can also be applied first to all testing units 4 so that the contact surfaces 6, 7 and 8 can then be placed on top. In a method step c), the metal sheets fastened to the conveying apparatus 3 by means of the carrier 9 are then machined by a cutting tool so that the surface of the contact surfaces 6, 7, 8 has the desired geometry. The contact surfaces 6, 7, 8 and the conveying apparatus 3 can thus easily be manufactured from different metal materials. Bores for the fluidic connection of the contact surfaces 6, 7 and 8 to the pipe system 23 of the conveying apparatus 3 (cf. FIG. 13) can also be subsequently introduced.

Of course, machining of the contact surfaces 6, 7 and 8 can also be carried out if the carrier 9 is formed by a detachable carrier element, as shown in FIGS. 1, 2 and 6-14.

FIG. 17 shows an alternative embodiment in which the planar elements 2 are transported by means of a separate transport system 28 along a conveying path 29 from a receiving point 30 to a delivery point 31. At the receiving point 30, the planar elements 2 are picked up by a first transport drum 45 and delivered to a second transport drum 56 at a delivery point 31. The conveying apparatus 3 is designed to contact multiple of its testing units 4 with the planar elements 2 conveyed by the transport system 28 with a defined pressure while they are being transported. The first, exposed separator 10 (see FIGS. 3 and 4) faces the direction of the testing apparatus 4. Accordingly, the planar elements 2 rest on the transport system 28 by means of the outer electrode 13. In this embodiment, the contact between the testing unit 4 and the corresponding planar element 2 is maintained almost along the entire conveying path 29. For this purpose, the conveying apparatus 3 moves the testing units 4 around the transport system 28 by means of a continuous track in a crescent shape, the smaller crescent radius, i.e., the inner radius, extending around a part of the transport system 28. In this embodiment, the transport system 28 is designed as a pure transport drum, in which the planar elements 2 are held on the lateral surface by the effect of a negative pressure. Alternatively, however, it is also possible for the transport system 28 itself to be designed as a test drum, so that the tests of this test drum and the tests carried out by the testing units 4 of the conveying apparatus 3 complement each other.

In a further possible embodiment, the conveying apparatus 3 serves only to press on the planar elements 2—as an alternative or in addition to suction by means of negative pressure—and then does not necessarily have to carry out a measurement itself. The advantage of this is a more constant pressure for a reproducible measurement.

### LIST OF REFERENCE SIGNS

1 Testing device
2 Planar element
3 Conveying apparatus
4 Testing unit
5 Stationary part
6 First contact surface
7 Second contact surface
8 Third contact surface
9 Carrier
10 Separator
11 Electrode
12 Separator
13 Electrode
14 Top of the carrier
15 Bottom of the carrier
16 First recess
17 Second recess
18 Third recess
19 Air duct
20 Flow-through region
21 Cable duct
22 Cable
23 Pipe system
24 Hollow shaft
25 Lateral surface
26 Switching matrix
27 Measuring device
28 Transport system
29 Conveying path
30 Receiving point
31 Delivery point
32 Axis of rotation
33 Through-opening
34 Conductor lug
35 Conductor lug
36 Groove
37 End face (of the carrier)
38 Protective sheath
39 Ground contact screw
40 Inner conductor
41 Insulation
42 Outer conductor
43 End face (of the ground contact screw)
44 Cover
45 First transport drum
46 First electronic unit
47 Second electronic unit
48 Third electronic unit
49 Input cable set
50 Sliding contact apparatus
51 Measuring cable set
52 Input channels
53 Output channels
54 Rotor
55 Stator
56 Second transport drum
57 Blind hole bore
58 Blind hole bore
59 Blind hole bore
60 Internal thread
61 Internal thread
62 Internal thread

1. A testing device for the energy cell production industry, wherein the testing device is designed for testing planar elements that are suitable for forming a cell stack, wherein
the testing device comprises multiple testing units which can be moved relative to a stationary part of the testing device by means of a conveying apparatus, wherein
the testing units each comprise at least two contact surfaces for making electrical and/or signal-transmitting contact with a planar element that is to be tested, wherein
the testing units each comprise a carrier which has electrically insulating properties and by means of which the contact surfaces of the relevant testing unit are supported in a predefined position and orientation with respect to one another, and wherein
the carriers of the testing units are fastened to the conveying apparatus.

2. The testing device (1) according to claim 1, wherein
the conveying apparatus is formed by a rotatably mounted drum, on the radially outer lateral surface of which the testing units are fastened.

3. The testing device according to claim 1, wherein
the testing units each comprise a first and a second contact surface which are designed for making electrical and/or signal-transmitting contact with two electrodes of a planar element when the planar element is in contact with the testing unit, and wherein
the testing units each comprise a third contact surface for making electrical and/or signal-transmitting contact with a separator of the planar element in contact with the testing unit.

4. The testing device according to claim 1, wherein
the contact surfaces are each formed by a metal sheet.

5. The testing device according to claim 1, wherein
the contact surfaces are fastened to the carrier by means of an integral bond or form-fitting connection.

6. The testing device according to claim 1, wherein
the carrier is formed by a detachable carrier element which is fastened to the conveying apparatus by a fastening means.

7. The testing device according to claim 1, wherein
the carrier is formed by an adhesive layer.

8. The testing device according to claim 1, wherein
recesses are provided in a top of the carrier and are designed to correspond in shape to the contact surfaces.

9. The testing device according to claim 1, wherein
the carrier has multiple air ducts which fluidically connect a bottom of the carrier to a top of the carrier.

10. The testing device according to claim 9, wherein
at least one of the contact surfaces per testing unit has at least one flow-through region which is in operative connection with at least one of the air ducts of the relevant carrier.

11. The testing device according to claim 1, wherein
the carrier comprises at least one cable duct in which a cable that is connected electrically and/or for signal transmission to one of the contact surfaces is guided.

12. The testing device according to claim 1, wherein
the testing units are each designed to receive and transport a planar element.

13. The testing device according to claim 1, wherein
a transport system is provided for transporting planar elements along a conveying path from a receiving point to a delivery point, wherein
the conveying apparatus is designed to bring one or more of its testing units into contact with a planar element while said element is being transported by the transport system, and wherein
the contact between the testing unit and the corresponding planar element is maintained along some of the conveying path or the entire conveying path.

14. The testing device according to claim 1, wherein
at least one measuring device is provided, wherein
at least two of the contact surfaces of each of the testing units can be connected to the at least one measuring device by means of a switching matrix.

15. The testing device according to claim 14, wherein
multiple measuring devices are provided, wherein
the switching matrix is designed to connect, electrically and/or for signal transmission, one or more of the contact surfaces of each of the testing units to different measuring devices.

16. The testing device according to claim 1, wherein
the testing units each comprise a first and a second contact surface which are designed for making electrical and/or signal-transmitting contact with two electrodes of a planar element when the planar element is in contact with the testing unit, wherein
the testing units each comprise a third contact surface for making electrical and/or signal-transmitting contact with a separator of the planar element in contact with the testing unit,
wherein
at least one measuring device is provided, wherein
at least two of the contact surfaces of each of the testing units can be connected to the at least one measuring device by means of a switching matrix, and wherein
the switching matrix is designed
to connect the first and the second contact surface simultaneously to the same measuring device;
to connect the first and the third contact surface simultaneously to the same measuring device; and/or
to connect the second and the third contact surface simultaneously to the same measuring device.

17. The testing device according to claim 14, wherein
the switching matrix is designed to wire the three contact surfaces of each of the testing units differently so that measurements can be carried out in different electrical circuits by means of the at least one measuring device.

18. The testing device according to claim 14, wherein
the at least one measuring device is designed to measure the real part and/or the imaginary part of the impedance, for example the electrical capacitance and/or the ohmic resistance, and/or to carry out a breakdown measurement.

19. A production method for producing the testing device according to claim 1, wherein
in a method step a), oversized metal sheets are provided to form the contact surfaces;
in a method step b), the metal sheets are fastened to the conveying apparatus by means of the carriers; and wherein
in a method step c), the metal sheets fastened to the conveying apparatus by means of the carrier are machined by a cutting tool.

20. A method for testing planar elements that are provided to form a cell stack for the energy cell production industry, wherein
the planar elements are tested using a testing device according to claim 1, wherein the planar elements to be tested are each in contact with the contact surfaces of one of the testing units.
